(19) United States
(12) Patent Application Publication
(10) Pub. No.: US 2024/0153790 A1
(43) Pub. Date: May 9, 2024

(54) PROCESS CHAMBER WITH PRESSURE CHARGING AND PULSING CAPABILITY

(71) Applicant: Applied Materials, Inc., Santa Clara, CA (US)

(72) Inventors: Borui Xia, San Jose, CA (US); Chih-Hsun Hsu, San Jose, CA (US); Xiaoxiong Yuan, San Jose, CA (US); Le Zhang, Fremont, CA (US); David T. Or, Santa Clara, CA (US); Jiang Lu, Milpitas, CA (US)

(73) Assignee: Applied Materials, Inc., Santa Clara, CA (US)

(21) Appl. No.: 18/387,649

(22) Filed: Nov. 7, 2023

Related U.S. Application Data
(60) Provisional application No. 63/423,443, filed on Nov. 7, 2022.
(60) Provisional application No. 63/458,252, filed on Apr. 10, 2023.

(51) Int. Cl. H01L 21/67; H01L 21/311

(52) U.S. Cl. CPC H01L 21/67069; H01L 21/31116

(57) ABSTRACT

Processing chambers including at least one gas reservoir connected to and in fluid communication with the lid through a fast-switching valve and a gas reservoir line are described. Processing methods, for example, etching methods, using the processing chambers are also described.

### CROSS-REFERENCE TO RELATED APPLICATIONS

This application claims priority to U.S. Provisional Application No. 63/423,443, filed Nov. 7, 2022, and U.S. Provisional Application No. 63/458,252, filed Apr. 10, 2023, the entire disclosures of which are hereby incorporated by reference herein.

### TECHNICAL FIELD

Embodiments of the disclosure generally relate to apparatus and methods for pre-clean and/or etching applications. In particular, embodiments of the disclosure relate to process chambers and methods for pressure charging and pulsing of an etchant for pre-clean/etch applications.

### BACKGROUND

Reliably producing submicron and smaller features is one of the key requirements of very large scale integration (VLSI) and ultra large scale integration (ULSI) of semiconductor devices. However, with the continued miniaturization of circuit technology, the dimensions of the size and pitch of circuit features, such as interconnects, have placed additional demands on processing capabilities. The various semiconductor components (e.g., interconnects, vias, capacitors, transistors) require precise placement of high aspect ratio features. Reliable formation of these components is critical to further increases in device and density.

Additionally, the electronic device industry and the semiconductor industry continue to strive for larger production yields while increasing the uniformity of layers deposited on substrates having increasingly larger surface areas. These same factors in combination with new materials also provide higher integration of circuits per unit area on the substrate. The need for greater process control regarding layer characteristics increases with the movement to smaller device features.

During semiconductor manufacturing, it is often advantageous to selectively etch a material from one surface compared to a separate surface. For example, etching a particular film from a dielectric surface without removing the film from a neighboring metal (or other dielectric) surface.

In many instances, etching a film requires exposure of the substrate to one or more etchant gas for a short duration. The amount of time that the substrate is exposed to the etchant impacts the selectivity of the etch process. Generally, an increase in the exposure time to the etchant gas results in a decrease in etch selectivity. Existing processing chambers are not able to pulse (both charging and purging of the process region) an etchant sufficiently quickly to maintain high selectivity between oxide and nitride surfaces.

Accordingly, there is a need in the art for apparatus and methods to improve etch selectivity.

### SUMMARY

One or more embodiments of the disclosure are directed to processing chambers comprising a chamber body having sidewalls and a bottom. A lid is on the chamber body enclosing a process volume. At least one gas reservoir connected to and in fluid communication with the lid through a fast-switching valve and a gas reservoir line.

Additional embodiments of the disclosure are directed to methods for selectively etching a substrate. The methods comprise exposing a substrate in a process volume of a processing chamber to a flow of at least one etchant gas for an etch time from at least one gas reservoir on a processing chamber lid. The substrate has a first material and a second material. The at least one gas reservoir is connected to the processing chamber lid through a fast-switching valve. The at least one etchant gas selectively etches a third material from the first material relative to the second material. The process volume is purged of the etchant gas.

Further embodiments of the disclosure are directed to processing chambers comprising a chamber body having sidewalls and a bottom. A lid is on the chamber body and encloses a process volume. A process gas inlet in one or more of the chamber body or lid configured to provide a flow of a process gas into process volume. A first gas reservoir is connected to and in fluid communication with the lid through a fast-switching valve and a first gas reservoir line. The first gas reservoir has a first etchant gas comprising a predetermined mixture of an etchant and a carrier gas. A second gas reservoir is connected to and in fluid communication with the lid through the fast-switching valve and a second gas reservoir line. The second gas reservoir has a second etchant gas comprising a predetermined mixture of an etchant and a carrier gas. Each of the first gas reservoir and second gas reservoir has a volume sufficient to maintain a constant high level etchant flow to the process volume throughout a pulse less than or equal to 3 seconds.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates a processing chamber with gas reservoirs and a gas box according to one or more embodiment of the disclosure;

FIG. 2 illustrates a cross-sectional schematic view of a processing chamber with gas reservoirs and a gas box according to one or more embodiment of the disclosure;

FIG. 3 illustrates a graph of the etch amount as a function of time for different materials illustrating an incubation delay; and

FIG. 4 illustrates a gas flow schematic according to one or more embodiment of the disclosure.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “substrate” refers to a surface, or portion of a surface, upon which a process acts. It will also be understood by those skilled in the art that reference to a substrate can also refer to only a portion of the substrate, unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate surface.

As used in this specification and appended claims, “substrate support” and “substrate support pedestal” may be used interchangeably.

As used in this specification and appended claims, use of relative terms like “above” and “below” should not be taken as limiting the scope of the disclosure to a physical orientation in space. Accordingly, use of relative terms should not be limited to the direction specified by gravity.

Existing processing chamber hardware is able to perform directional etch processes using RF pulsing or regular etch reactions. However, existing hardware cannot perform an “etchant pulsing” process to achieve high SiO/SiN etch selectivity. As used in this specification and the appended claims, the use of generic chemical formulas such as SiO refers to a material that has silicon and oxygen atoms in any suitable ratio, unless otherwise specified. For example, an SiN film may contain Si₃N₄ or about three silicon atoms for about every four nitrogen atoms. The skilled artisan will recognize that the atomic composition of the film may not adhere strictly to the target stoichiometric ratios. Accordingly, the use of generic formulae (e.g., SiO or SiN) is for identification purposes only.

Some embodiments of the disclosure provide deposition and etch capable process chambers. In some embodiments, an etch-CVD combined chamber with a revised etch chamber body with smaller cavity is described. In some embodiments, the combined chamber includes heating capability. In some embodiments, the combined chamber is configured to handle special etchants that might be hazardous to use with existing chamber hardware.

RF pulsing and directional etch cannot reach ideal selectivity and may compromise the SiN spacer in certain applications causing leakage current. Some embodiments of the disclosure provide etchant pulsing capabilities to improve SiO/SiN selectivity. Some embodiments advantageously provide the capability to achieve high SiO/SiN selectivity. In some embodiments, the SiN spacer can be preserved while the SiO is being etched. In some embodiments, the improved selectivity of the etch process decreases failure due to leakage current as the result of the loss of SiN.

Some embodiments of the disclosure provide process chambers with one or more etchant reservoir and fast-switching valves. In some embodiments, the etchant can be charged to a high pressure in a reservoir allowing fast filling of the process cavity to start the etching process. The etchant can be rapidly pumped out of the process cavity after a precisely controlled reaction time. The reaction time can be small with the fast operation of the fast-switching valve. This is referred to as “etchant pulsing”.

Some embodiments of the disclosure provide a revised Etch chamber body with a smaller cavity and heating capability along with a bi-polar electrostatic chuck. These can be used to enable special etchants and wide pressure regions (several Torr to mTorr).

Some embodiments of the disclosure provide a new gas delivery system with individual gas injection (IGI) capability, reservoir and fast-switching valve. The special etchants are IGI, which means that they have separate gas lines from other gases to the chamber lid. IGI gas lines and lids may be heated. In some embodiments, the separation and heating avoid condensation caused by mixing the special etchants with each other or to other gases. Reservoirs and fast-switching valves may be integrated to the etchant gas lines.

In some embodiments, the process chamber lid and gas distribution plate/showerhead are based on a modified CVD-type hardware with heating capability. This advantageously helps mix and distribute the etchant with good uniformity.

The process of some embodiments uses a high SiO/SiN etch selectivity with efficient isotropic cleaning capability.

The process mechanism for high selectivity according to some embodiments uses an incubation delay where only the SiO is etched for the first few seconds of the reaction. The etchant pulsing of some embodiments is controlled so that the etching reaction remains within the incubation delay region. The closeness of the etchant gas reservoirs to the process region allows for the etching reaction to remain within the incubation delay time frame. When using a conventional processing chamber gas box or house gas lines, the time to replace the gases within the process region is too long so that the reaction cannot remain in the incubation delay time frame and there is no selective etching of the SiO relative to the SiN.

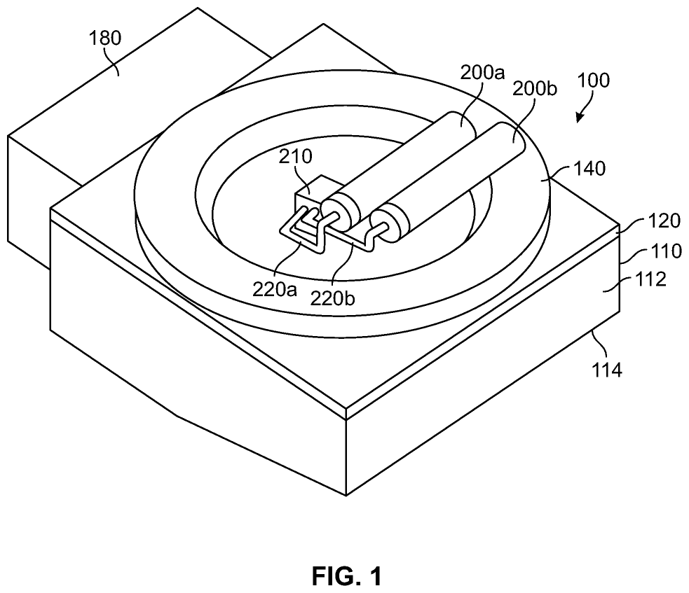

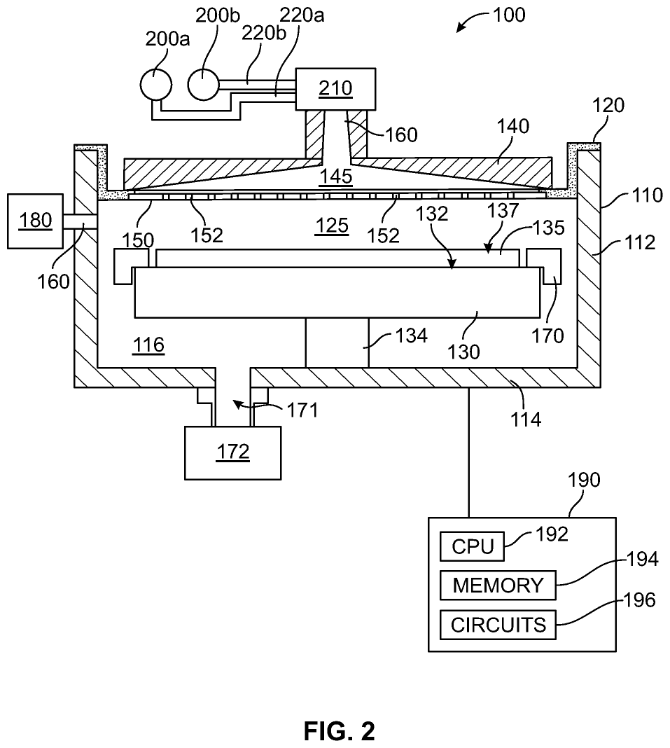

Referring to FIGS. 1 and 2, one or more embodiments of the disclosure are directed to a processing chamber 100. The processing chamber 100 has a chamber body 110 with at least one sidewall 112 and a bottom 114 enclosing an interior volume 116.

A substrate support 130 is located within the interior volume 116. The substrate support 130 has a support surface 132 that is configured to support a wafer 135 (also referred to as a substrate) during processing. The substrate support 130 of some embodiments is positioned on a support shaft 134 located within the interior volume 116. The support shaft 134 of some embodiments is configured to move the substrate support 130 closer to and further from the lid 120 of the processing chamber 100.

A lid 120 is on the chamber body 110 and encloses a process volume 125. The lid 120 of some embodiments is able to heat up to at least 100° C. or higher. The process volume 125 is a portion of the interior volume 116 of the processing chamber 100 between the support surface 132 of the substrate support 130 and the lid 120. The process volume 125 of some embodiments can be volumetrically minimized to increase the speed at which the gases within the process volume 125 can be replaced. A smaller process volume 125 allows for rapid switching between different, potentially incompatible, process gases.

The lid 120 of some embodiments includes a backing plate 140 and a showerhead 150. A plenum 145 is formed between the backing plate 140 and the showerhead 150. A gas can be flowed into the plenum 145 to pass through the apertures 152 in the showerhead 150 and into the process volume 125.

In some embodiments, the processing chamber 100 includes a process gas inlet 160 in the sidewall 112 of the chamber body 110. The process gas inlet 160 is configured to provide a flow of process gas into the process volume 125. In some embodiments, the process gas inlet 160 is in one or more of the chamber body 110 or lid 120. In some embodiments, the process gas inlet 160 is configured to provide a flow of a process gas parallel to the surface 137 of the wafer 135. In some embodiments, the process gas inlet 160 is configured to provide a flow of a process gas perpendicular to the surface 137 of the wafer 135. In some embodiments, there is a process gas inlet 160 in the sidewall 112 of the chamber body 110 and a process gas inlet 160 in the lid 120.

The process gas inlet 160 of some embodiments is located in the sidewall 112 of the chamber body 110 and flows the process gas into the process volume 125 from the sidewall. To prevent or minimize process gas flowing into the interior volume 116 of the processing chamber 100, in some embodiments, an edge ring 170 is positioned around the substrate support 130.

The process chamber 100 includes at least one exhaust outlet 171 which can be connected to a vacuum source 172. Suitable vacuum sources 172 include, but are not limited to, house vacuum lines or stand-alone vacuum pumps. In some embodiments, as shown in FIG. 2, the at least one exhaust outlet 171 is located in the bottom 114 of the chamber body 110. In some embodiments, the at least one exhaust outlet 171 is located in the sidewall 112 of the chamber body 110 on an opposite side of the process chamber 100 from the process gas inlet 160.

One or more embodiments of the disclosure include at least one gas reservoir connected to the lid 120. The at least one gas reservoir is connected to and in fluid communication with the lid 120 through a fast-switching valve 210 and a gas reservoir line. In some embodiments, as shown in the illustrated embodiments, there are two gas reservoirs, a first gas reservoir 200a and a second gas reservoir 200b. The first gas reservoir 200a is connected to and in fluid communication with the lid 120 through a first gas reservoir line 220a and the fast-switching valve 210. The second gas reservoir 200b is connected to and in fluid communication with the lid 120 through a second gas reservoir line 220b and the fast-switching valve 210. As used in this specification and the appended claims, a fast-switching valve is a type of valve with a fast open/close capability. Fast-switching valves typically have a response time less than or equal to 50 milliseconds.

The volume of the at least one gas reservoirs can be any suitable volume. In order to reduce the response time, the reservoirs close to the lid 120 and fast-switching valve 210 may be advantageous, resulting in hardware limitation for the reservoirs. Within the hardware limitation, a bigger volume reservoir would be generally preferred for stable gas flow. In some embodiments, the at least one gas reservoir has a volume greater than or equal to 100 cc, 200 cc, 300 cc, 400 cc, 500 cc, 600 cc, 700 cc, 800 cc, 900 cc or 1000 cc.

The length of the gas reservoir lines connecting the gas reservoirs to the fast-switching valve 210 is minimized to ensure rapid changing of the composition of gases in the process volume 125. In some embodiments, each gas reservoir line has a length less than or equal to 20 mm.

According to some embodiments, at least one of the gas reservoirs has a volume sufficient to maintain a constant high level etchant flow to the process volume 125 throughout a pulse less than or equal to 3 seconds.

The gas reservoirs of some embodiments are used to allow rapid changing of the process gases within the process volume 125 to allow for a selective etch process to maintain selectivity. In some embodiments, each of the gas reservoirs comprises on specific type of etchant. In some embodiments, each of the gas reservoirs comprise a predetermined mixture of a reactant and a carrier gas. The carrier gas acts as a diluent to form a predetermined concentration of the etchant so that the gas can flow from the gas reservoir to the process volume 125 without a separate push gas (carrier gas).

In some embodiments, the processing chamber 100 includes a gas box 180. The gas box 180 of some embodiments is configured to provide a flow of a process gas to the process volume 125 that is separate from the gas reservoir lines. In some embodiments, the gas box 180 is configured to provide a flow of a process gas through process gas inlet 160 in the sidewall 112 of the chamber body 110 to the process volume 125 that is a different composition from the gas in any of the at least one gas reservoirs.

The processing chamber 100 of some embodiments further comprises a controller 190. The controller 190 is coupled to the processing chamber 100 by any suitable communication connections known to the skilled artisan. The controller 190 may control the operation of the processing chamber 100 via control of valves, flow regulators, temperature controllers, etc., that are a normal part of a semiconductor manufacturing process chamber.

The controller 190 generally includes a central processing unit (CPU) 192, memory 194, and support circuits 196. The CPU 192 may be one of any form of a general-purpose processor that can be used in an industrial setting. The memory 194, or non-transitory computer-readable medium, is accessible by the CPU 192 and may be one or more of memory such as random-access memory (RAM), read only memory (ROM), floppy disk, hard disk, or any other form of digital storage, local or remote. The support circuits 196 are coupled to the CPU 192 and may comprise cache, clock circuits, input/output subsystems, power supplies, and the like. The various methods disclosed herein may generally be implemented under the control of the CPU 192 by the CPU 192 executing computer instruction code stored in the memory 194 (or in memory of a particular process chamber) as, for example, a software routine. When the computer instruction code is executed by the CPU 192, the CPU 192 controls the process chamber to perform processes in accordance with the various methods.

In some embodiments, the controller 190 has a least one configuration selected from a configuration to control a flow of gas from the first gas reservoir 200a, a flow of gas from the second gas reservoir 200b, a flow of gas through the process gas inlet 160 or the fast-switching valve 210.

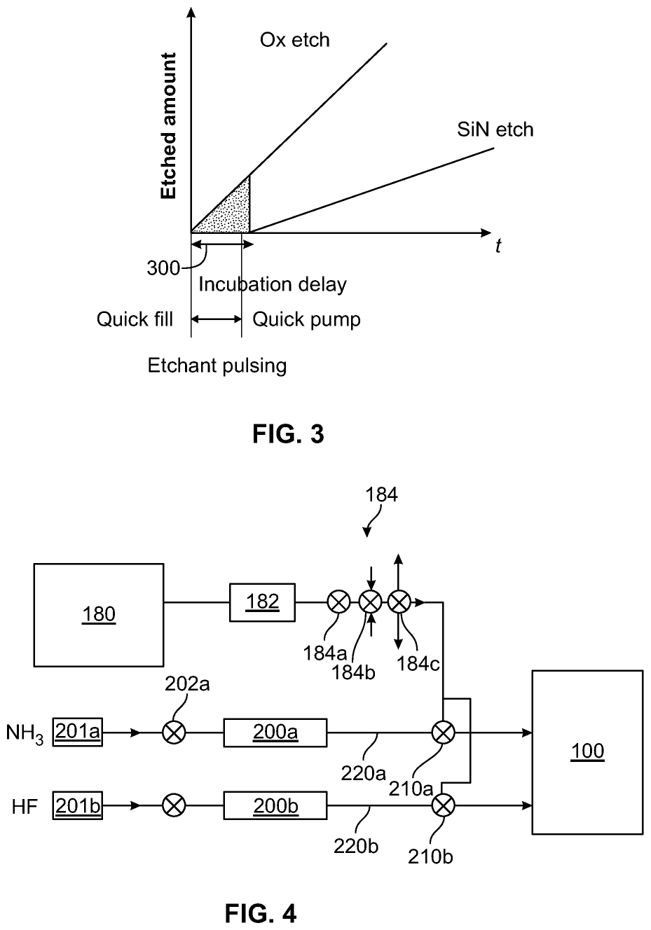

FIG. 3 illustrates a graph of the amount of film etched from a surface as a function of time for a silicon oxide and a silicon nitride surface. As seen in this graph, etching of the silicon oxide film begins shortly after exposure to the etching environment, while there is a period of time before the silicon nitride film begins to etch. This time period is referred to as the incubation delay, also referred to as an incubation delay period 300. The length of the incubation delay depends on, for example, the etch temperature, etchant concentration and the film composition (e.g., density). According to some embodiments, the processing chamber 100 is configured pulse an etchant gas into the process volume 125 for a length of time less than the incubation delay. A pulse of etchant gas includes both the charging of the process volume 125 with the etchant chemistry and purging of the process volume 125 to remove the etchant chemistry. The etchant gas can be pulsed into the process volume 125 multiple times to remove a predetermined amount of the silicon oxide film without substantially changing the thickness of the silicon nitride film. As used in this manner, the term “substantially changing the thickness” means that the thickness of the stated film does not increase or decrease by greater than 10%, 5%, 2% or 1% relative to the initial thickness.

FIG. 4 illustrates a flow control schematic of a process chamber and related apparatus according to one or more embodiments of the disclosure. The gas box 180 has one or more process gases which may include precursor ampoules or other gas sources. Gas flows from the gas box 180 through a flow rate controller 182, which may be inside or outside the gas box 180. A valve cluster 184 downstream of the flow rate controller 182 includes a shut-off valve 184a, inert gas purge valve 184b and a dump valve 184c, as the skilled artisan will understand.

First gas reservoir 200a is shown connected to a first upstream gas source 201a through an upstream shutoff valve 202a which can be used to refill first gas reservoir 200a. This allows the first gas reservoir 200a to be closer to the process volume 125 than the gas box 180, allowing for faster charging of the process volume 125 with first gas.

Second gas reservoir 200b is shown connected to a second upstream gas source 201b through an upstream shutoff valve 202b which can be used to refill second gas reservoir 200b. This allows the second gas reservoir 200b to be closer to the process volume 125 than the gas box 180, allowing for faster charging of the process volume 125 with second gas.

The etch cycle of some embodiments is sufficiently short to remain within the incubation delay period 300. The etch cycle is defined as the amount of time, reservoir pressure delta, or total gas flow, starting at beginning to charge the process volume 125 with reactive gas and ending when substantially all of the reactive gas has been purged from the process volume 125. As used in this manner, “substantially all of the reactive gas has been purged” means that there is less than 1%, 0.5% or 0.1% of the reactive gas remaining in the process volume 125 relative to the peak concentration of reactive gas during the etch cycle. The total etch time is the sum of the amount of time for each etch cycle. For example, ten etch cycles of one second each has a total etch time of ten seconds. In some embodiments, the etch time for any given etch cycle is less than or equal to 3 seconds, 2 seconds or 1 second.

The at least one gas reservoir is located within a minimum distance from the process volume to ensure an etching cycle less than 3 seconds. In some embodiments, each of the first gas reservoir 200a and second gas reservoir 200b are located within a minimum distance from the process volume to ensure an etching cycle less than 3 seconds.

In some embodiments, the processing methods further comprises providing a flow of a process gas into the process volume 125 of the processing chamber 100 from a gas box 180 connected to the processing chamber 100. The gas box 180 is configured to provide a flow of the process gas to the process volume 125 separate from each of the gas reservoir lines.

In some embodiments, the etch chamber body comprises an etchant-resistant chamber body with a special coating. In some embodiments, the special coating is configured to resist corrosion from halogen-based species such as fluorine or chlorine. In some embodiments, the modified chamber has a reduced volume in the chamber reaction cavity. In some embodiments, the volume in the chamber reaction cavity is less than or equal to 40 L, 35 L, 30 L or 25 L. In some embodiments, the bi-polar electrostatic chuck (ESC) handles a wide pressure region. In some embodiments, the bi-polar ESC is configured to operate in a pressure in the range of 0.1 μtorr to 1000 torr.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. A processing chamber comprising:
a chamber body having sidewalls and a bottom;
a lid on the chamber body enclosing a process volume; and
at least one gas reservoir connected to and in fluid communication with the lid through a fast-switching valve and a gas reservoir line.

2. The processing chamber of claim 1, wherein there are two reservoirs.

3. The processing chamber of claim 2, wherein the two reservoirs contain different etchants.

4. The processing chamber of claim 3, wherein each of the reservoirs comprise a predetermined mixture of a reactant and carrier gas.

5. The processing chamber of claim 1, wherein the at least one gas reservoir has a volume greater than or equal to 100 cc.

6. The processing chamber of claim 1, wherein the at least one gas reservoir has a volume sufficient to maintain a constant high level etchant flow to the process volume throughout a pulse less than or equal to 3 seconds.

7. The processing chamber of claim 1, wherein each gas reservoir line has a length less than or equal to 20 cm.

8. The processing chamber of claim 1, further comprising a gas box connected to the processing chamber, the gas box configured to provide a flow of a process gas to the process volume separate from each of the gas reservoir lines.

9. A method for selectively etching a substrate, method comprising:
exposing a substrate in a process volume of a processing chamber to a flow of at least one etchant gas for an etch time from at least one gas reservoir on a processing chamber lid, the substrate having a first material and a second material, the at least one gas reservoir connected to the processing chamber lid through a fast-switching valve, the at least one etchant gas selectively etching a third material from the first material relative to the second material; and
purging the process volume of the etchant gas.

10. The processing method of claim 9, wherein the etch time is less than or equal to 3 seconds.

11. The processing method of claim 9, wherein the at least one gas reservoir is located within a minimum distance from the process volume to ensure an etching cycle less than 3 seconds.

12. The processing method of claim 9, wherein the at least one gas reservoir has a volume greater than or equal to 800 cc.

13. The processing method of claim 9, wherein there are two gas reservoirs.

14. The processing method of claim 13, wherein the two reservoirs comprise different etchants.

15. The processing method of claim 14, wherein the etchant gas comprises a mixture of two etchants flowed separately into the processing chamber from the two gas reservoirs.

16. The processing method of claim 14, wherein each of the gas reservoirs comprise a predetermined mixture of a reactant and carrier gas.

17. The processing method of claim 14, wherein each gas reservoir line has a length less than or equal to 20 cm.

18. The processing method of claim 14, further comprising providing a flow of a process gas into the process volume of the processing chamber from a gas box connected to the processing chamber, the gas box configured to provide a flow of the process gas to the process volume separate from each of the gas reservoir lines.

19. A processing chamber comprising:
a chamber body having sidewalls and a bottom;
a lid on the chamber body enclosing a process volume;
a process gas inlet in one or more of the chamber body or lid configured to provide a flow of a process gas into process volume;
a first gas reservoir connected to and in fluid communication with the lid through a fast-switching valve and a first gas reservoir line, the first gas reservoir having a first etchant gas comprising predetermined mixture of an etchant and a carrier gas; and
a second gas reservoir connected to and in fluid communication with the lid through the fast-switching valve and a second gas reservoir line, the second gas reservoir having a second etchant gas comprising a predetermined mixture of an etchant and a carrier gas,
wherein each of the first gas reservoir and second gas reservoir has a volume sufficient to maintain a constant high level etchant flow to the process volume throughout a pulse less than or equal to 3 seconds.

20. The processing chamber of claim 19, further comprising a controller configured to control a flow of gas from the first gas reservoir, a flow of gas from the second gas reservoir, a flow of gas through the process gas inlet and the fast-switching valve.
